(19) United States
(12) Patent Application Publication
(10) Pub. No.: US 2024/0030681 A1
(43) Pub. Date: Jan. 25, 2024

(54) LIGHT-EMITTING DEVICE, PROJECTOR, DISPLAY, AND HEAD-MOUNTED DISPLAY

(71) Applicant: SEIKO EPSON CORPORATION, Tokyo (JP)

(72) Inventors: Takashi MIYATA, Shiojiri-Shi (JP); Yoji KITANO, Chino-Shi (JP)

(73) Assignee: SEIKO EPSON CORPORATION, Tokyo (JP)

(21) Appl. No.: 18/354,666

(22) Filed: Jul. 19, 2023

(30) Foreign Application Priority Data
Jul. 21, 2022 (JP) 2022-116435

(51) Int. Cl. H01S 5/042; H01S 5/34

(52) U.S. Cl. CPC H01S 5/0425; H01S 5/34; G03B 21/2033

(57) ABSTRACT

A light-emitting device includes a light-emitting unit, an insulating layer, and a conductive layer to which a predetermined potential is applied. The light-emitting unit includes a first semiconductor layer, a second semiconductor layer having a conductivity type different from a conductivity type of the first semiconductor layer, and a light-emitting layer provided between the first semiconductor layer and the second semiconductor layer. The insulating layer covers the light-emitting unit. The conductive layer is provided in the insulating layer and electrically separated from the light-emitting unit.

The present application is based on, and claims priority from JP Application Serial Number 2022-116435, filed Jul. 21, 2022, the disclosure of which is hereby incorporated by reference herein in its entirety.

### BACKGROUND

### 1. Technical Field

The present disclosure relates to a light-emitting device, a projector, a display, and a head-mounted display.

### 2. Related Art

Semiconductor lasers are expected as next-generation light sources with high brightness. Among such semiconductor lasers, one using a nanocolumn is expected to achieve high-output light emission with a small radiation angle based on a photonic crystal effect exhibited by the nanocolumn.

For example, Japanese Unexamined Patent Application Publication (Translation of PCT Application) No.2008/544567 describes a light-emitting device including an n-type GaN buffer layer, a plurality of GaN nanorods, a transparent electrode provided at distal end portions of the GaN nanorods, and a transparent insulator layer provided between the n-type GaN buffer layer and the transparent electrode.

In the light-emitting device as described above, for example, when the transparent insulator layer is processed, electric charges may be accumulated in the transparent insulator layer. The electric charges accumulated in the transparent insulator layer affects the characteristics of the light-emitting device.

### SUMMARY

A light-emitting device according to one aspect of the present disclosure includes a light-emitting unit, an insulating layer, and a conductive layer to which a predetermined potential is applied. The light-emitting unit includes a first semiconductor layer, a second semiconductor layer having a conductivity type different from a conductivity type of the first semiconductor layer, and a light-emitting layer provided between the first semiconductor layer and the second semiconductor layer. The insulating layer covers the light-emitting unit. The conductive layer is provided in the insulating layer and electrically separated from the light-emitting unit.

One aspect of a projector according to the present disclosure includes one aspect of the above-described light-emitting device.

One aspect of a display according to the present disclosure includes one aspect of the above-described light-emitting device.

One aspect of a head-mounted display according to the present disclosure includes one aspect of the above-described light-emitting device.

### BRIEF DESCRIPTION OF THE DRAWINGS

FIG. 1 is a cross-sectional view schematically illustrating a light-emitting device according to the present embodiment.

FIG. 2 is a plan view schematically illustrating the light-emitting device according to the present embodiment.

FIG. 3 is a plan view schematically illustrating the light-emitting device according to the present embodiment.

FIG. 4 is a cross-sectional view schematically illustrating a manufacturing step of the light-emitting device according to the present embodiment.

FIG. 5 is a cross-sectional view schematically illustrating a manufacturing step of the light-emitting device according to the present embodiment.

FIG. 6 is a cross-sectional view schematically illustrating a manufacturing step of the light-emitting device according to the present embodiment.

FIG. 7 is a cross-sectional view schematically illustrating a manufacturing step of the light-emitting device according to the present embodiment.

FIG. 8 is a plan view schematically illustrating a projector according to the present embodiment.

FIG. 9 is a plan view schematically illustrating a display according to the present embodiment.

FIG. 10 is a cross-sectional view schematically illustrating the display according to the present embodiment.

FIG. 11 is a perspective view schematically illustrating a head-mounted display according to present embodiment.

FIG. 12 is a diagram schematically illustrating an image forming device and a light guiding device of the head-mounted display according to the present embodiment.

### DESCRIPTION OF EXEMPLARY EMBODIMENTS

Preferred exemplary embodiments of the present disclosure will be described in detail with reference to accompanying drawings hereinafter. Note that the exemplary embodiment described hereinafter is not intended to unjustly limit the content of the present disclosure as set forth in the claims. In addition, all of the configurations described hereinafter are not necessarily essential constituent requirements of the present disclosure.

### 1. Light-Emitting Device

### 1.1. Configuration

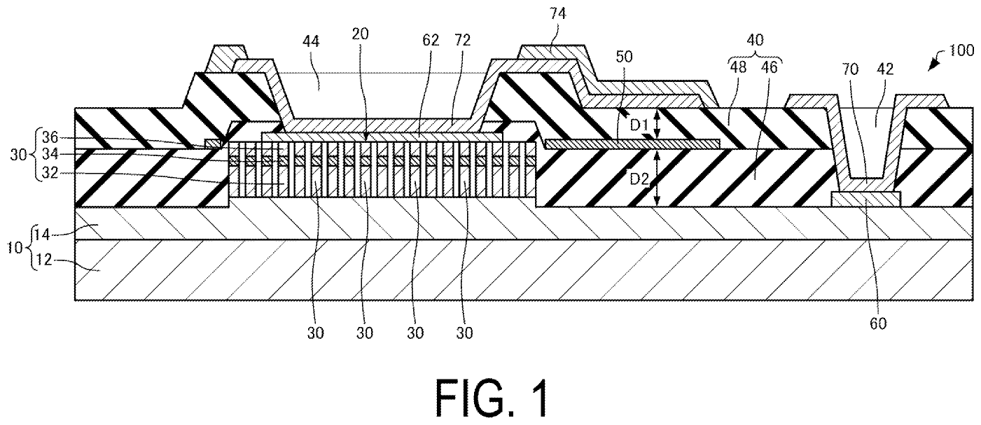

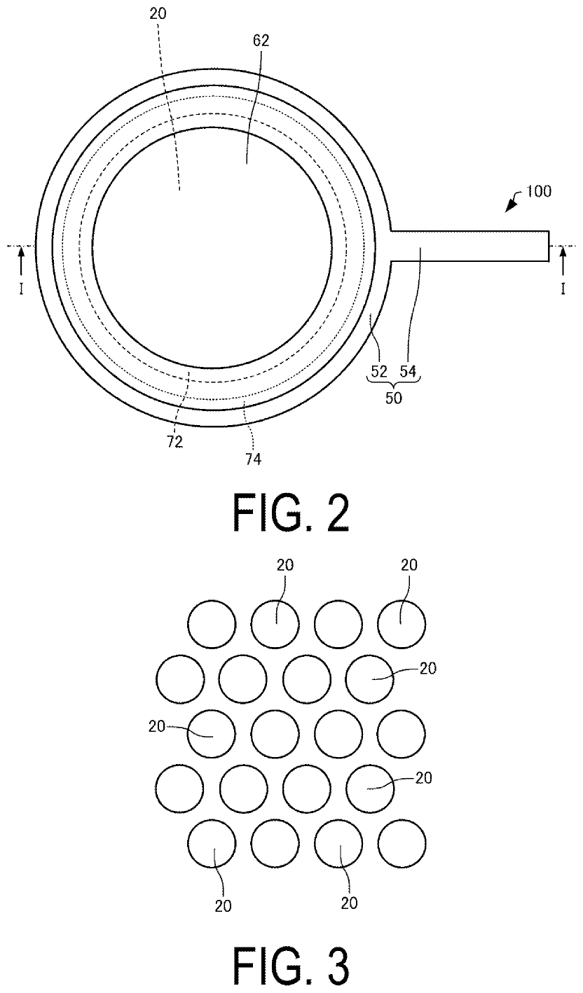

First, a light-emitting device according to the present embodiment will be described with reference to the accompanying drawings. FIG. 1 is a cross-sectional view schematically illustrating a light-emitting device 100 according to the present embodiment. FIG. 2 is a plan view schematically illustrating a light-emitting device 100 according to the present embodiment. FIG. 3 is a cross-sectional view taken along line I-I in FIG. 2.

As illustrated in FIGS. 1 and 2, the light-emitting device 100 includes, for example, a substrate 10, a light-emitting unit 20, an insulating layer 40, a conductive layer 50, a first electrode 60, a second electrode 62, first wiring 70, second wiring 72, and third wiring 74. The light-emitting device 100 is, for example, a semiconductor laser. For the sake of convenience, in FIG. 2, the second wiring 72 and the third wiring 74 are illustrated in a see-through manner with members other than the conductive layer 50 and the first electrode 60 omitted.

As illustrated in FIG. 1, the substrate 10 includes, for example, a support substrate 12 and a buffer layer 14. The support substrate 12 is a Si substrate, a GaN substrate, a sapphire substrate, a SiC substrate, or the like for example.

The buffer layer 14 is provided on the support substrate 12. The buffer layer 14 is, for example, an n-type GaN layer doped with Si. Although not illustrated, a mask layer for growing a columnar portion 30 of the light-emitting unit 20 may be provided on the buffer layer 14. The mask layer is, for example, a titanium layer, a silicon oxide layer, a titanium oxide layer, an aluminum oxide layer, or the like.

In the present specification, a description is given with a stacking direction of a first semiconductor layer 32 and a light-emitting layer 34 of the columnar portion 30 (hereinafter, may be simply referred to as “stacking direction”) defined based on the light-emitting layer 34 of the columnar portion 30. Specifically, a direction from the light-emitting layer 34 toward a second semiconductor layer 36 of the columnar portion 30 is defined as “upward” and a direction from the light-emitting layer 34 toward the first semiconductor layer 32 is defined as “downward”. Further, a direction orthogonal to the stacking direction is also referred to as “in-plane direction”.

The light-emitting unit 20 is provided at the substrate 10. In the illustrated example, the light-emitting unit 20 is provided on the buffer layer 14. The light-emitting unit 20 includes, for example, a plurality of columnar portions 30.

The columnar portions 30 are provided at the substrate 10. The columnar portions 30 protrude upward from the substrate 10. The columnar portions 30 protrude upward from the buffer layer 14 provided on the support substrate 12. The columnar portion 30 is also called, for example, a nanocolumn, a nanowire, a nanorod, or a nanopillar. The planar shape of the columnar portion 30 is a polygon such as regular hexagon or a circle for example.

The diameter of the columnar portion 30 is, for example, 50 nm or more and 500 nm or less. With the columnar portion 30 having a diameter of 500 nm or less, the light-emitting layer 34 of high-quality crystal can be obtained, and distortion in the light-emitting layer 34 can be reduced. Thus, the light generated in the light-emitting layer 34 can be amplified with high efficiency.

Note that the “diameter of the columnar portion 30” is a diameter when the planar shape of the columnar portion 30 is a circle, and is a diameter of the minimum inclusion circle when the planar shape of the columnar portion 30 is a shape other than the circle. For example, the diameter of the columnar portion 30 is the diameter of the smallest circle that includes the polygon therein when the planar shape of the columnar portion 30 is a polygon, and is the diameter of the smallest circle that includes the ellipse therein when the planar shape of the columnar portion 30 is an ellipse.

A plurality of columnar portions 30 are provided. The plurality of columnar portions 30 are separated from each other. In the illustrated example, there is a gap between the adjacent columnar portions 30. A spacing between adjacent ones of the columnar portions 30 is, for example, 1 nm or more and 500 nm or less. The plurality of columnar portions 30 are arranged at a predetermined pitch in a predetermined direction when viewed from the stacking direction. The plurality of columnar portions 30 are arranged in, for example, a regular triangular lattice pattern or a square lattice pattern. The plurality of columnar portions 30 can exhibit the photonic crystal effect.

Note that the “pitch of the columnar portions 30” is a distance between the centers of adjacent ones of the columnar portions 30 in a predetermined direction. The “center of the columnar portion 30” is a center of a circle when the planar shape of the columnar portion 30 is the circle, and is a center of the minimum inclusion circle when the planar shape of the columnar portion 30 is a shape other than the circle. For example, the center of the columnar portion 30 is, when the planar shape of the columnar portion 30 is a polygon, the center of the smallest circle that includes the polygon therein, and is, when the planar shape of the columnar portion 30 is an ellipse, the center of the smallest circle that includes the ellipse therein.

The columnar portion 30 includes the first semiconductor layer 32, the light-emitting layer 34, and the second semiconductor layer 36. The first semiconductor layer 32, the light-emitting layer 34, and the second semiconductor layer 36 are, for example, a group III nitride semiconductor and have a wurtzite crystal structure.

The first semiconductor layer 32 is provided on the buffer layer 14. The first semiconductor layer 32 protrudes upward from the buffer layer 14. The first semiconductor layer 32 is provided between the substrate 10 and the light-emitting layer 34. The first semiconductor layer 32 is a semiconductor layer of a first conductivity type. For example, the first conductivity type is n-type. The first semiconductor layer 32 is, for example, an n-type GaN layer doped with Si.

The light-emitting layer 34 is provided on the first semiconductor layer 32. The light-emitting layer 34 is provided between the first semiconductor layer 32 and the second semiconductor layer 36. The light-emitting layer 34 generates light when a current is injected thereinto. The light-emitting layer 34 includes, for example, a well layer and a barrier layer. The well layer and the barrier layer are i-type semiconductor layers which are not intentionally doped with impurities. The well layer is, for example, the InGaN layer. The barrier layer is, for example, the GaN layer. The light-emitting layer 34 has a multiple quantum well (MQW) structure composed of the well layer and the barrier layer.

Note that the numbers of the well layers and the barrier layers composing the light-emitting layer 34 are not particularly limited. For example, only one well layer may be provided, and in this case, the light-emitting layer 34 has a single quantum well (SQW) structure.

The second semiconductor layer 36 is provided on the light-emitting layer 34. The second semiconductor layer 36 is provided between the light-emitting layer 34 and the second electrode 62. The second semiconductor layer 36 is a semiconductor layer of a second conductivity type different from the first conductivity type. For example, the second conductivity type is p-type. The second semiconductor layer 36 is, for example, a p-type GaN layer doped with Mg. The first semiconductor layer 32 and the second semiconductor layer 36 are clad layers having a function of confining light in the light-emitting layer 34.

Although not illustrated, an optical confinement layer (OCL) including an i-type InGaN layer and a GaN layer may be provided between the first semiconductor layer 32 and the light-emitting layer 34 and/or between the light-emitting layer 34 and the second semiconductor layer 36. The second semiconductor layer 36 may include an electron blocking layer (EBL) formed of a p-type AlGaN layer.

In the light-emitting device 100, a pin diode is constituted by the second semiconductor layer 36 of the p-type, the light-emitting layer 34 which is the i-type and not intentionally doped with impurities, and the first semiconductor layer 32 of the n-type. In the light-emitting device 100, when a forward bias voltage of the pin diode is applied between the first electrode 60 and the second electrode 62, a current is injected into the light-emitting layer 34, and electrons and positive holes are recombined in the light-emitting layer 34. This recombination causes light emission. The light generated in the light-emitting layer 34 propagates in the in-plane direction, forms a standing wave by the photonic crystal effect exhibited by the plurality of columnar portions 30, and receives a gain in the light-emitting layer 34. Thus, laser is oscillated. Then, the light-emitting device 100 emits a +1st order diffracted light and a −1st order diffracted light as the laser light in the stacking direction.

Although not illustrated, a reflective layer may be provided between the support substrate 12 and the buffer layer 14 or below the support substrate 12. The reflective layer is, for example, a distributed Bragg reflector (DBR) layer. The reflective layer can reflect the light generated in the light-emitting layer 34, so that the light-emitting device 100 can emit light only from the second electrode 62 side.

The insulating layer 40 is provided at the substrate 10 and the light-emitting unit 20. The insulating layer 40 covers the substrate 10 and the light-emitting unit 20. The insulating layer 40 is provided with a first contact hole 42 and a second contact hole 44. The bottom surface of the first contact hole 42 is constituted by the first electrode 60. The bottom surface of the second contact hole 44 is constituted by the second electrode 62.

As illustrated in FIG. 1, the insulating layer 40 includes, for example, a first layer 46 and a second layer 48. The first layer 46 is provided at the substrate 10 and the light-emitting unit 20. The first layer 46 is provided between the substrate 10 and the conductive layer 50. The first layer 46 is, for example, a layer made of nitride. When the first layer 46 is a layer made of nitride, the water resistance of the light-emitting device 100 can be improved. The first layer 46 is, for example, a silicon nitride (SiN) layer, a silicon oxynitride (SiON) layer, or the like. Note that the first layer 46 may be a silicon oxide (SiO₂) layer.

The second layer 48 is provided on the first layer 46 and the conductive layer 50. The second layer 48 is provided between the conductive layer 50 and the second wiring 72. The dielectric constant of the second layer 48 is, for example, lower than the dielectric constant of the first layer 46. The second layer 48 is, for example, a layer made of an organic material. When the first layer 46 is a layer made of an organic material, the flatness of the upper surface of the insulating layer 40 can be improved. Thus, the flatness of the second wiring 72 can be improved. The second layer 48 is a polyimide layer or the like, for example. Note that the second layer 48 may be a silicon oxide layer. Thus, the material constituting the first layer 46 and the material constituting the second layer 48 may be different from each other. The dielectric constant of the first layer 46 and the dielectric constant the second layer 48 may be different from each other.

The conductive layer 50 is provided in the insulating layer 40. In the illustrated example, the upper surface, the lower surface, and the side surface of the conductive layer 50 are in contact with the insulating layer 40. The conductive layer 50 is provided between the first layer 46 and the second layer 48 of the insulating layer 40. The conductive layer 50 is provided between the substrate 10 and the second wiring 72. The conductive layer 50 is provided between the substrate 10 and the third wiring 74. The conductive layer 50 is electrically separated from the light-emitting unit 20. The conductive layer 50 is separated from the light-emitting unit 20.

The thickness of the conductive layer 50 is, for example, 10 nm or more and 100 nm or less, and is preferably 30 nm or more and 70 nm or less. A distance D1 between the conductive layer 50 and the second wiring 72 in the stacking direction is, for example, shorter than a distance D2 between the conductive layer 50 and the substrate 10 in the stacking direction. In the stacking direction, the conductive layer 50 is provided father from the substrate 10 than the light-emitting layer 34 is. In the illustrated example, the conductive layer 50 is provided above the light-emitting layer 34.

The conductive layer 50 surrounds the light-emitting unit 20 when viewed in the stacking direction. The conductive layer 50 does not overlap with the light-emitting unit 20 when viewed in the stacking direction. As illustrated in FIG. 2, the conductive layer 50 includes, for example, a ring-shaped first portion 52 and a rod-shaped second portion 54 coupled to the first portion 52.

The sheet resistance of the conductive layer 50 is lower than the sheet resistance of the buffer layer 14. The sheet resistance of the conductive layer 50 is lower than, for example, the sheet resistance of the electrodes 60 and 62 and the wiring 70, the wiring 72, and the wiring 74. The conductive layer 50 has conductivity. The conductive layer 50 is a metal layer. The conductive layer 50 is, for example, a titanium (Ti) layer or a titanium tungsten (TiW) layer.

A predetermined potential is applied to the conductive layer 50. The conductive layer 50 is coupled to an external terminal not illustrated. The conductive layer 50 is not in a floating state. The potential applied to the conductive layer 50 is, for example, different from the potential applied to the first electrode 60. The potential applied to the conductive layer 50 is, for example, different from the potential applied to the second electrode 62.

The potential applied to the conductive layer 50 is, for example, a potential between the potential applied to the first electrode 60 and the potential applied to the second wiring 72. Alternatively, the potential applied to the conductive layer 50 is the same as the potential applied to the first electrode 60. Alternatively, the potential applied to the conductive layer 50 is the same as the potential applied to the second wiring 72. When the first electrode 60 is a cathode and the second electrode 62 is an anode, the potential applied to the conductive layer 50 is, for example, higher than the potential applied to the first electrode 60 and lower than the potential applied to the second wiring 72. The potential applied to the conductive layer 50 is, for example, a potential between the potential applied to the first wiring 70 and the potential applied to the third wiring 74. The potential applied to the conductive layer 50 may be a ground potential. The predetermined potential applied to the conductive layer 50 may be changed during the operation of the light-emitting device 100.

As illustrated in FIG. 1, the first electrode 60 is provided at the substrate 10. In the illustrated example, a portion of the buffer layer 14 is etched, and the first electrode 60 is provided in the etched portion of the buffer layer 14. The buffer layer 14 may be in ohmic contact with the first electrode 60. The first electrode 60 is provided between the buffer layer 14 and the first wiring 70. The first electrode 60 is electrically coupled to the first semiconductor layer 32. In the illustrated example, the first electrode 60 is electrically coupled to the first semiconductor layer 32 via the buffer layer 14.

As the first electrode 60, one formed by, for example, stacking a Cr layer, a Ni layer, and an Au layer in this order from the buffer layer 14 side or the like is used. The first electrode 60 is one electrode configured to inject a current into the light-emitting layer 34. The first electrode 60 is, for example, a cathode.

The second electrode 62 is on the side of the light-emitting unit 20 opposite to the substrate 10. The second electrode 62 is provided on the light-emitting unit 20. The second electrode 62 is provided between the light-emitting unit 20 and the second wiring 72. In the illustrated example, the second electrode 62 is provided on the second semiconductor layer 36. The second semiconductor layer 36 may be in ohmic contact with the second electrode 62. In the example illustrated in FIG. 2, the shape of the second electrode 62 is circle.

The second electrode 62 is formed by, for example, stacking a Pd layer, a Pt layer, a Ni layer, and an Au layer in this order from the second semiconductor layer 36 side, or is a single metal layer. The electrical resistivity of the second electrode 62 is lower than the electrical resistivity of the second wiring 72. The thickness of the second electrode 62 is smaller than the thickness of the second wiring 72. The second electrode 62 is the other electrode configured to inject a current into the light-emitting layer 34. The second electrode 62 is, for example, an anode.

As illustrated in FIG. 1, the first wiring 70 is provided on the first electrode 60 and the insulating layer 40. The first wiring 70 is located in the first contact hole 42. The first wiring 70 is coupled to the first electrode 60. The material of the first wiring 70 is, for example, a layer in which a Cr layer and an Au layer are stacked in this order from the first electrode 60 side, or a single metal layer.

The second wiring 72 is provided on the second electrode 62 and the insulating layer 40. The second wiring 72 is located in the second contact hole 44. The second wiring 72 is coupled to the second electrode 62. The second wiring 72 overlaps with the light-emitting unit 20 and the second electrode 62 when viewed in the stacking direction. The material of the second wiring 72 is a material that transmits light generated in the light-emitting layer 34. The material of the second wiring 72 is, for example, indium tin oxide (ITO), ZnO, or the like.

The third wiring 74 is provided on the second wiring 72 and the insulating layer 40. The third wiring 74 is not located in the second contact hole 44. The third wiring 74 does not overlap with, for example, the second electrode 62 when viewed in the stacking direction. The third wiring 74 is electrically coupled to the second electrode 62 via the second wiring 72. The material of the third wiring 74 is, for example, the same as that of the first wiring 70.

While the light-emitting layer 34 described above is InGaN based, the light-emitting layer 34 may be made of various materials capable of emitting light when a current is injected thereto, depending on the wavelength of light to be emitted. For example, semiconductor materials that are AlGaN based, AlGaAs based, InGaAs based, InGaAsP based, InP based, GaP based, AlGaP based, and the like can be used.

The light-emitting device 100 is not limited to a laser, and may be a light emitting diode (LED).

The number of light-emitting units 20 is not particularly limited. For example, as illustrated in FIG. 3, a plurality of the light-emitting units 20 may be provided. In this case, the conductive layer 50 is disposed between the adjacent light-emitting units 20. The first electrode 60 and the second electrode 62 may be configured to independently supply a current to each of the plurality of light-emitting units 20. In the illustrated example, the plurality of light-emitting units 20 are arranged in a regular triangular lattice pattern when viewed in the stacking direction. For the sake of convenience, members other than the light-emitting unit 20 are omitted in FIG. 3.

### 1.2. Effects

The light-emitting device 100 includes: the substrate 10, the light-emitting unit 20 including the first semiconductor layer 32, the second semiconductor layer 36 having a conductivity type different from a conductivity type of the first semiconductor layer 32, and the light-emitting layer 34 provided between the first semiconductor layer 32 and the second semiconductor layer 36, the insulating layer 40 that covers the light-emitting unit 20, and the conductive layer 50 to which a predetermined potential is applied, the conductive layer 50 being provided in the insulating layer 40 and electrically separated from the light-emitting unit 20.

Therefore, in the light-emitting device 100, the electric charges accumulated in the insulating layer 40 can be released to the outside by the conductive layer 50. Thus, the electric charges accumulated in the insulating layer 40 can be reduced. As a result, an impact of the electric charges accumulated in the insulating layer 40 on the characteristics of the light-emitting device 100 can be reduced.

For example, a large amount of electric charges accumulated in the insulating layer lead to a slow response of the light-emitting unit, rendering a quick switching operation, that is, a quick ON/OFF operation impossible. Therefore, for example, when a plurality of light-emitting units are provided, there may be a light-emitting unit that is turned OFF with a delay despite an intention to turn OFF all the light-emitting units, or there may be a light-emitting unit that is turned ON with a delay despite an intention to turn ON all the light-emitting units. In addition, in a case where a light-emitting unit that emits red light, a light-emitting unit that emits green light, and a light-emitting unit that emits blue light are provided, a small amount of blue light remains to lead to whitening despite an intention to turn OFF all of the light-emitting units to obtain black color, and despite and intention to turn ON all of the light-emitting units, emission of blue light delays to lead to compromised color balance resulting in color shift.

Such problems can be avoided with the light-emitting device 100 in which the electric charges accumulated in the insulating layer 40 can be reduced by the conductive layer 50 as described above.

The light-emitting device 100 includes the substrate 10, the first electrode 60 that is provided at the substrate 10 and electrically coupled to the first semiconductor layer 32, the second electrode 62 that is provided on the side of the light-emitting unit 20 opposite to the substrate 10 and electrically coupled to the second semiconductor layer 36, and the second wiring 72 that is provided at the insulating layer 40 and coupled to the second electrode 62. The first semiconductor layer 32 is provided between the substrate 10 and the light-emitting layer 34, the conductive layer 50 is provided between the substrate 10 and the second wiring 72, and the predetermined potential applied to the conductive layer 50 is a potential between the potential applied to the first electrode 60 and the potential applied to the second wiring 72, is same as the potential applied to the first electrode 60, or is same as the potential applied to the second wiring 72. Thus, in the light-emitting device 100, the electric field between the substrate 10 and the second wiring 72 can be blocked by the conductive layer 50, and the capacitance due to the substrate 10, the second wiring 72, and the insulating layer 40, that is, the parasitic capacitance can be reduced.

In the light-emitting device 100, the light-emitting unit 20 includes the plurality of columnar portions 30, and each of the plurality of columnar portions 30 includes the first semiconductor layer 32, the second semiconductor layer 36, and the light-emitting layer 34. Therefore, in the light-emitting device 100, dislocations generated in the light-emitting layer 34 can be reduced, and the light-emitting layer 34 of a high quality crystal can be obtained.

In the light-emitting device 100, the distance D1 between the conductive layer 50 and the second wiring 72 is shorter than the distance D2 between the conductive layer 50 and the substrate 10. The second wiring 72 is provided at a position more likely to be exposed to noise than the substrate 10. Therefore, with the distance D1 set to be shorter than the distance D2, the noise that has entered from the second wiring 72 can be blocked by the conductive layer 50 before the noise reaches a deep portion of the insulating layer 40. Thus, the light-emitting device 100 can have stable characteristics.

In the light-emitting device 100, in the stacking direction, the conductive layer 50 is provided father from the substrate 10 than the light-emitting layer 34 is. Therefore, in the light-emitting device 100, the noise that has entered from the second wiring 72 can be blocked by the conductive layer 50 before the noise reaches a deep portion of the light-emitting layer 34. Thus, the light-emitting device 100 can have stable characteristics.

In the light-emitting device 100, the conductive layer 50 surrounds the light-emitting unit 20 when viewed in the stacking direction. Therefore, in the light-emitting device 100, the electric charges accumulated around the light-emitting unit 20 can be reduced by the conductive layer 50.

In the light-emitting device 100, the insulating layer 40 includes the first layer 46 provided between the substrate 10 and the conductive layer 50 and the second layer 48 provided between the conductive layer 50 and the second wiring 72, and the dielectric constant of the second layer 48 is smaller than the dielectric constant of the first layer 46. Therefore, in the light-emitting device 100, it is possible to reduce the parasitic capacitance on the second wiring 72 side where noise is likely to enter. Thus, the light-emitting device 100 can have stable characteristics.

### 2. Method of Manufacturing Light-Emitting Device

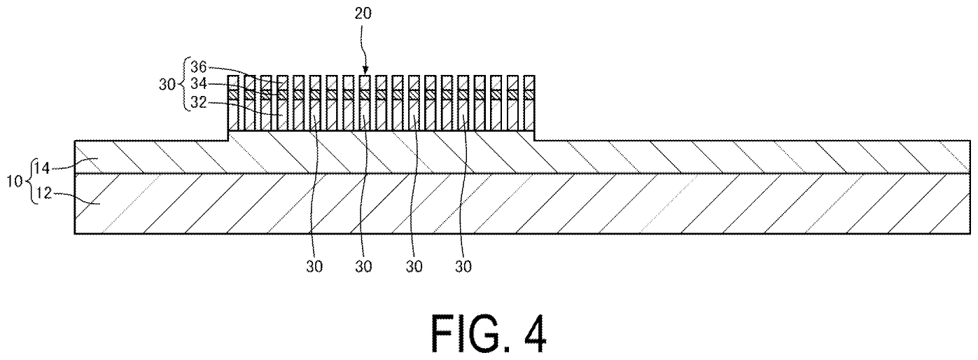

Next, a method of manufacturing the light-emitting device 100 according to the present embodiment will be described with reference to the accompanying drawings. FIGS. 4 to 7 are cross-sectional views schematically illustrating manufacturing steps of the light-emitting device 100 according to the present embodiment.

As illustrated in FIG. 4, the buffer layer 14 is epitaxially grown on the support substrate 12. Examples of the method of epitaxial growth include a metal organic chemical vapor deposition (MOCVD) method, a molecular beam epitaxy (MBE) method, and the like. With this process, the substrate 10 can be formed.

Next, a mask layer (not illustrated) is formed on the buffer layer 14. The mask layer is formed by, for example, an electron beam vapor deposition method, a sputtering method, or the like.

Next, the first semiconductor layer 32, the light-emitting layer 34, and the second semiconductor layer 36 are epitaxially grown in this order on the buffer layer 14 using the mask layer as a mask. Examples of the method of epitaxial growth include the MOCVD method, the MBE method, and the like. With this process, the plurality of columnar portions 30 can be formed. In the illustrated example, after the plurality of columnar portions 30 have been formed, the buffer layer 14 may be partially etched by etching.

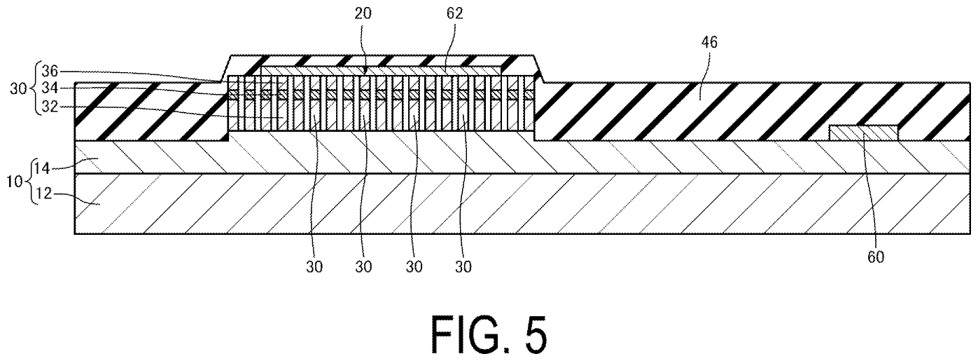

As illustrated in FIG. 5, the second electrode 62 is formed on the columnar portions 30. Next, the first electrode 60 is formed on the buffer layer 14. The first electrode 60 and the second electrode 62 are formed by, for example, a sputtering method, a vacuum deposition method, or the like. Note that the order of the process of forming the first electrode 60 and the process of forming the second electrode 62 is not particularly limited.

Next, the first layer 46 is formed to cover the buffer layer 14, the first electrode 60, and the second electrode 62. The first layer 46 is formed by, for example, a spin coat method or a chemical vapor deposition (CVD) method.

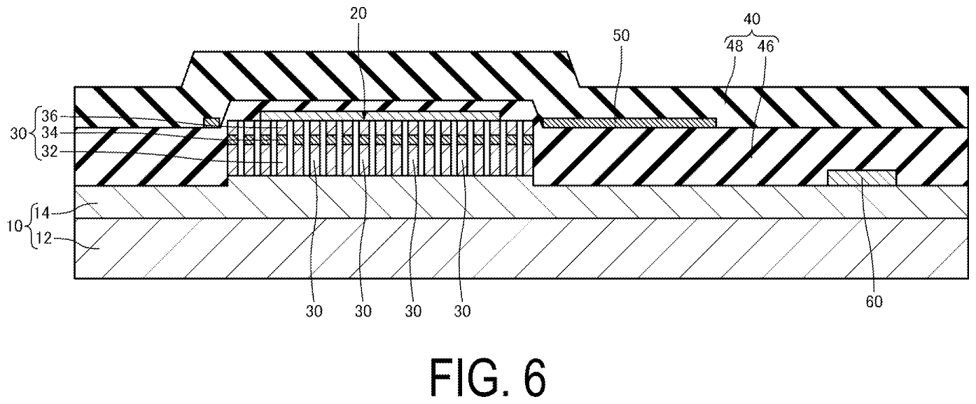

As illustrated in FIG. 6, the conductive layer 50 is formed on the first layer 46. The conductive layer 50 is formed by, for example, a sputtering method, a CVD method, or a vacuum deposition method.

Next, the second layer 48 is formed to cover the first layer 46 and the conductive layer 50. The second layer 48 is formed by, for example, a spin coating method or a CVD method. The second layer 48 and the first layer 46 may be formed by the same method or different methods. With this process, the insulating layer 40 can be formed.

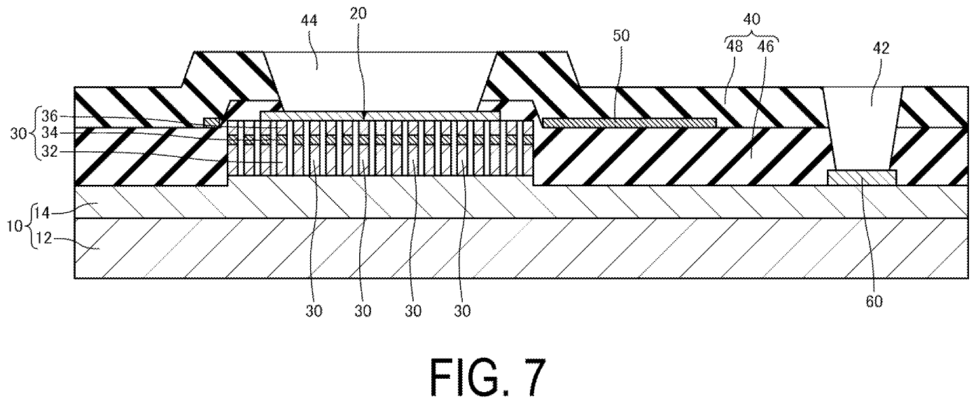

As illustrated in FIG. 7, the insulating layer 40 is patterned to form the first contact hole 42 exposing the first electrode 60 and the second contact hole 44 exposing the second electrode 62. The patterning is performed by, for example, photolithography and etching. The etching may be wet etching or dry etching. In this process, electric charges may be trapped and accumulated in the insulating layer 40. Still, in the light-emitting device 100, the electric charges accumulated in the insulating layer 40 can be reduced by the conductive layer 50.

As illustrated in FIG. 1, the second wiring 72 is formed on the second electrode 62. Next, the first wiring 70 is formed on the first electrode 60, and the third wiring 74 is formed on the second wiring 72. The first wiring 70 and the third wiring 74 are formed by the same process, for example. The wiring 70, the wiring 72, and the wiring 74 are formed by, for example, a sputtering method, a CVD method, or a vacuum deposition method.

The light-emitting device 100 can be manufactured by the above processes.

### 3. Projector

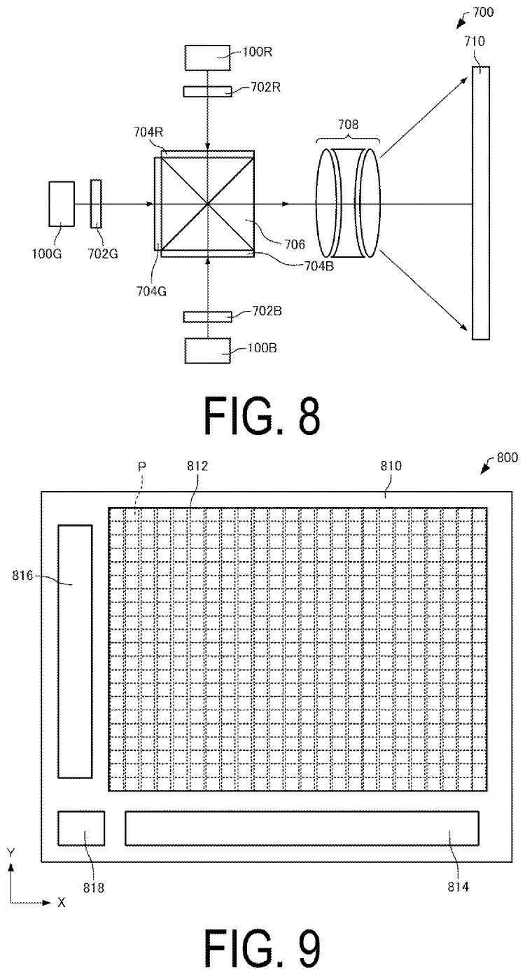

Next, a projector according to the present embodiment will be described with reference to the accompanying drawings. FIG. 8 is a plan view schematically illustrating a projector 700 according to the present embodiment.

The projector 700 includes, for example, the light-emitting device 100 as a light source.

The projector 700 includes a housing (not illustrated) and a red light source 100R, a green light source 100G, and a blue light source 100B that are provided in the housing and emit red light, green light, and blue light, respectively. For the sake of convenience, the red light source 100R, the green light source 100G, and the blue light source 100B are simplified in FIG. 8.

The projector 700 further includes a first optical element 702R, a second optical element 702G, a third optical element 702B, a first optical modulation device 704R, a second optical modulation device 704G, a third optical modulation device 704B, and a projection device 708 which are provided in the housing. The first optical modulation device 704R, the second optical modulation device 704G, and the third optical modulation device 704B are, for example, transmissive liquid crystal light valves. The projection device 708 is, for example, a projection lens.

The light emitted from the red light source 100R is incident on the first optical element 702R. The light emitted from the red light source 100R is condensed by the first optical element 702R. Note that the first optical element 702R may have a function other than the condensing. The same applies to the second optical element 702G and the third optical element 702B described below.

The light condensed by the first optical element 702R is incident the first optical modulation device 704R. The first optical modulation device 704R modulates the incident light, based on image information. Then, the projection device 708 enlarges the image formed by the first optical modulation device 704R and projects the image on a screen 710.

The light emitted from the green light source 100G is incident on the second optical element 702G. The light emitted from the green light source 100G is condensed by the second optical element 702G.

The light condensed by the second optical element 702G is incident on the second optical modulation device 704G. The second optical modulation device 704G modulates the incident light, based on the image information. Then, the projection device 708 enlarges the image formed by the second optical modulation device 704G and projects the image on the screen 710.

The light emitted from the blue light source 100B is incident on the third optical element 702B. The light emitted from the blue light source 100B is condensed by the third optical element 702B.

The light condensed by the third optical element 702B is incident the third optical modulation device 704B. The third optical modulation device 704B modulates the incident light, based on the image information. Then, the projection device 708 enlarges the image formed by the third optical modulation device 704B and projects the image on the screen 710.

The projector 700 further includes a cross dichroic prism 706 that synthesizes the light emitted from the first optical modulation device 704R, the light emitted from the second optical modulation device 704G, and the light emitted from the third optical modulation device 704B and guides the resultant light to the projection device 708.

Light of three colors modulated by the first optical modulation device 704R, the second optical modulation device 704G, and the third optical modulation device 704B is incident on the cross dichroic prism 706. In the cross dichroic prism 706, four right-angle prisms are bonded together, and on inner surfaces of the prisms are provided with a dielectric multilayer film configured to reflect the red light and a dielectric multilayer film configured to reflect the blue light. The three types of color light are synthesized by these dielectric multilayer films, and light representing a color image is formed. The synthesized light is projected onto the screen 710 by the projection device 708, and an image is enlarged to be displayed.

With the light-emitting devices 100 of the red light source 100R, the green light source 100G, and the blue light source 100B controlled as pixels of an image based on the image information, the image may be directly formed without using the first optical modulation device 704R, the second optical modulation device 704G, and the third optical modulation device 704B. The projection device 708 may enlarge the image formed by the red light source 100R, the green light source 100G, and the blue light source 100B and project the enlarged image on the screen 710.

Although the transmissive liquid crystal light valve is used as the optical modulation device in the above example, a light valve other than the liquid crystal light valve may be used, or a reflective light valve may be used. Examples of such a light valve include a reflective liquid crystal light valve and a digital micro mirror device. In addition, the configuration of the projection device is appropriately changed depending on the type of the light valve used.

The light source can also be applied to a light source device of a scanning type image display device including a scanning unit which is an image forming device for displaying an image of a desired size on a display surface by scanning a screen with light from the light source.

### 4. Display

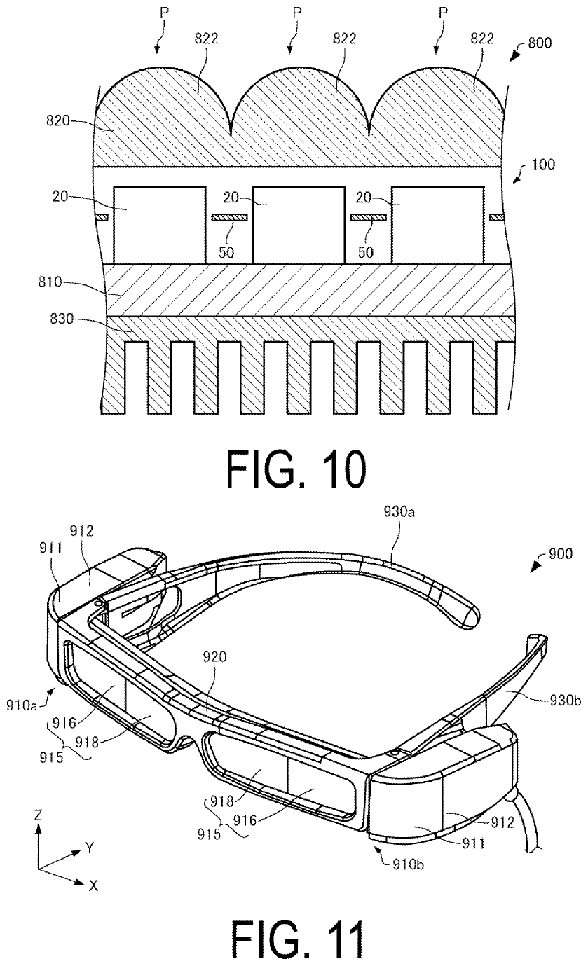

Next, a display according to the present embodiment will be described with reference to the accompanying drawings. FIG. 9 is a plan view schematically illustrating a display 800 according to the present embodiment. FIG. 10 is a cross-sectional view schematically illustrating the display 800 according to the present embodiment. Note that an x-axis and a y-axis are illustrated in FIG. 9 as two axes orthogonal to each other.

The display 800 includes, for example, the light-emitting device 100 including a plurality of the light-emitting units 20 as light sources.

The display 800 is a display device that displays an image. The image includes those only displaying character information. The display 800 is a self-luminous display. As illustrated in FIGS. 9 and 10, the display 800 includes, for example, a circuit board 810, a lens array 820, and a heat sink 830.

A drive circuit for driving the light-emitting unit 20 is mounted on the circuit board 810. The drive circuit is a circuit including a complementary metal oxide semiconductor (CMOS) and the like for example. The drive circuit drives the light-emitting unit 20 based on, for example, input image information. Although not illustrated, a translucent substrate for protecting the circuit board 810 is disposed on the circuit board 810.

The circuit board 810 includes, for example, a display region 812, a data line driving circuit 814, a scanning line driving circuit 816, and a control circuit 818.

The display region 812 includes a plurality of pixels P. In the illustrated example, the pixels P are arranged along the x-axis and the y-axis. The light-emitting device 100 is disposed in the display region 812. In other words, the plurality of light-emitting units 20 are arranged in the display region 812. For the sake of convenience, in FIG. 10, the light-emitting unit 20 and the conductive layer 50 are illustrated among the components of the light-emitting device 100, and the other components of the light-emitting device 100 are omitted. In FIG. 10, the light-emitting unit 20 and the conductive layer 50 are illustrated in a simplified manner.

Although not illustrated, the circuit board 810 is provided with a plurality of scanning lines and a plurality of data lines. For example, the scanning lines extend along the x-axis and the data lines extend along the y-axis. The scanning lines are coupled to the scanning line driving circuit 816. The data lines are coupled to the data line driving circuit 814. In addition, the pixels P are provided to correspond to intersections between the plurality of scanning lines and the plurality of data lines.

The pixels P each include one light-emitting device 100, one lens 822, and a pixel circuit not illustrated, for example. In other words, the pixels P each include, for example, one light-emitting unit 20, one lens 822, and a pixel circuit not illustrated. The pixel circuit includes a switching transistor that functions as a switch for the pixel P. The switching transistor has the gate coupled to the scanning line, and has one of the source and the drain coupled to the data line.

The data line driving circuit 814 and the scanning line driving circuit 816 are circuits that control driving of the light-emitting device 100 constituting the pixel P. The control circuit 818 controls display of an image.

Image data is supplied to the control circuit 818 from an upper level circuit. The control circuit 818 supplies various signals based on the image data to the data line driving circuit 814 and the scanning line driving circuit 816.

When the scanning line is selected by activating the scanning signal by the scanning line driving circuit 816, the switching transistor provided in the selected pixel P is turned on. At this time, the data line driving circuit 814 supplies a data signal from the data line to the selected pixel P. As a result, the light-emitting device 100 of the selected pixel P emits light based on the data signal.

The lens array 820 includes a plurality of the lenses 822. For example, one lens 822 is provided for one light-emitting unit 20. Light emitted from light-emitting unit 20 is incident on one lens 822.

The conductive layer 50 is disposed between the adjacent light-emitting units 20. In a cross-sectional view taken along a direction orthogonal to the stacking direction, the conductive layer 50 is disposed to overlap with the outer edge of the lens 822 in the stacking direction. Thus, in the cross-sectional view along the direction orthogonal to the stacking direction, the conductive layer 50 is disposed to overlap with both of the adjacent lenses 822 in the stacking direction. Although not illustrated, the conductive layer 50 is disposed to overlap with the outer edge of the lens 822 in plan view as viewed in the stacking direction. That is, in plan view as viewed in the stacking direction, the conductive layer 50 is disposed to overlap with both of the adjacent lenses 822. The outer edge of the lens 822 serves as the boundary between adjacent lenses 822.

The heat sink 830 is in contact with the circuit board 810. The material of the heat sink 830 is, for example, a metal such as copper or aluminum. The heat sink 830 dissipates heat generated by the light-emitting device 100.

### 5. Head-Mounted Display

### 5.1 Overall Configuration

Next, a head-mounted display according to the present embodiment will be described with reference to the accompanying drawings. FIG. 11 is a perspective view schematically illustrating a head-mounted display 900 according to present embodiment. Note that, an x-axis, a y-axis, and a z-axis are illustrated in FIG. 11 as three axes orthogonal to each other.

As illustrated in FIG. 11, the head-mounted display 900 is a head-mounted display device that has an outer appearance of an eyewear. The head-mounted display 900 is mounted on the head of a viewer. The viewer is a user who uses the head-mounted display 900. The head-mounted display 900 allows the viewer to visually recognize image light of a virtual image and to visually recognize an external image in a see-through manner. The head-mounted display 900 can also be referred to as a virtual image display device.

The head-mounted display 900 includes a first display unit 910a, a second display unit 910b, a frame 920, a first temple 930a, and a second temple 930b for example.

The first display unit 910a and the second display unit 910b display images. Specifically, the first display unit 910a displays a virtual image for the right eye of the viewer. The second display unit 910b displays a virtual image for the left eye of the viewer. In the illustrated example, the first display unit 910a is provided on the negative side of the second display unit 910b in the x-axis direction. The display units 910a and 910b include, for example, an image forming device 911 and a light guiding device 915.

The image forming device 911 generates image light. The image forming device 911 includes, for example, an optical system such as a light source and a projection device, and an external member 912. The external member 912 houses the light source and the projection device.

The light guiding device 915 covers the front of the eyes of the viewer. The light guiding device 915 guides the image light formed by the image forming device 911 and allows the viewer to visually recognize external light and the image light in an overlapping manner. Details of the image forming device 911 and the light guiding device 915 will be described below.

The frame 920 supports the first display unit 910a and the second display unit 910b. For example, the frame 920 surrounds the display units 910a and 910b when viewed from the y-axis direction. In the illustrated example, the image forming device 911 of the first display unit 910a is attached to an end portion of the frame 920 on the negative side in the x-axis direction. The image forming device 911 of the second display unit 910b is attached to an end portion of the frame 920 on the positive side in the x-axis direction.

The first temple 930a and the second temple 930b extend from the frame 920. In the illustrated example, the first temple 930a extends toward the positive side in the y-axis direction from the end portion of the frame 920 on the negative side in the x-axis direction. The second temple 930b extends toward the positive side in the y-axis direction from the end portion of the frame 920 on the positive side in the x-axis direction.

The first temple 930a and the second temple 930b are put on the ears of the viewer when the head-mounted display 900 is worn by the viewer. The head of the viewer is positioned between the temples 930a and 930b.

### 5.2 Image Forming Device and Light Guiding Device

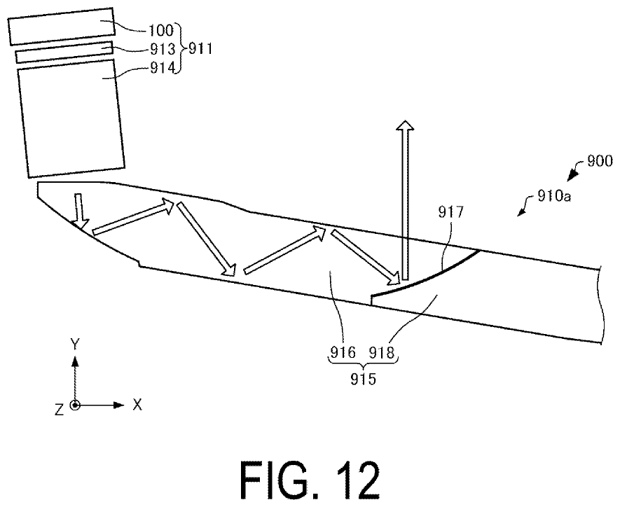

FIG. 12 is a diagram schematically illustrating the image forming device 911 and the light guiding device 915 of the first display unit 910a of the head-mounted display 900 according to the present embodiment. The first display unit 910a and the second display unit 910b have basically the same configuration. Therefore, the following description on the first display unit 910a is applicable to the second display unit 910b.

As illustrated in FIG. 12, the image forming device 911 includes, for example, the light-emitting device 100 as a light source, an optical modulation device 913, and a projection device 914 for image formation.

The optical modulation device 913 modulates the light incident from the light-emitting device 100 based on image information, and emits image light. The optical modulation device 913 is a transmissive liquid crystal light valve. The light-emitting device 100 may be a self-luminous light-emitting device that emits light based on the image information input. In this case, the optical modulation device 913 is not provided.

The projection device 914 projects the image light emitted from the optical modulation device 913 toward the light guiding device 915. The projection device 914 is, for example, a projection lens. As the lens constituting the projection device 914, a lens having an axially symmetric surface as a lens surface may be used.

The light guiding device 915 is accurately positioned with respect to the projection device 914 by being screwed to a lens barrel of the projection device 914, for example. The light guiding device 915 includes, for example, an image light guiding member 916 that guides the image light and a see-through member 918 for see-through view.

The image light emitted from the projection device 914 is incident on the image light guiding member 916. The image light guiding member 916 is a prism that guides the image light toward the eyes of the viewer. The image light incident on the image light guiding member 916 is repeatedly reflected on the inner surface of the image light guide member 916, and then is reflected by a reflective layer 917 to be emitted from the image light guiding member 916. The image light emitted from the image light guiding member 916 reaches the eyes of the viewer. In the illustrated example, the reflective layer 917 reflects the image light toward the positive side in the y-axis direction. The reflective layer 917 is formed of, for example, metal or a dielectric multilayer film. The reflective layer 917 may be a half mirror.

The see-through member 918 is adjacent to the image light guiding member 916. The see-through member 918 is fixed to the image light guiding member 916. The outer surface of the see-through member 918 is continuous with the outer surface of the image light guiding member 916, for example. The viewer sees the external light through the see-through member 918. The image light guiding member 916 also has the function of making the viewer see the external light therethrough, in addition to the function of guiding the image light.

The light-emitting device according to the embodiment described above can be used for devices other than the projector, the display, and the head-mounted display. The light-emitting device according to the above-described embodiment is used as a light source of, for example, indoor and outdoor lighting, a laser printer, a scanner, a vehicle-mounted light, a sensing device using light, a communication device, or the like.

The above-described embodiments and modifications are merely examples, and the present disclosure is not limited thereto. For example, the embodiments and the modifications may be combined as appropriate.

The present disclosure includes substantially the same configuration as the configurations described in the embodiments, for example, a configuration having the same function, method, and result or a configuration having the same object and effect. In addition, the present disclosure includes a configuration in which non-essential parts of the configurations described in the embodiments are replaced. In addition, the present disclosure includes a configuration that achieves the same effects or a configuration that can achieve the same object as the configurations described in the embodiments. In addition, the present disclosure includes a configuration in which a known technique is added to the configurations described in the embodiments.

The following contents are derived from the above-described embodiments and modifications.

A light-emitting device according to one aspect includes:
a light-emitting unit including a first semiconductor layer, a second semiconductor layer having a conductivity type different from a conductivity type of the first semiconductor layer, and a light-emitting layer provided between the first semiconductor layer and the second semiconductor layer,
an insulating layer that covers the light-emitting unit, and
a conductive layer to which a predetermined potential is applied, the conductive layer being provided in the insulating layer and electrically separated from the light-emitting unit.

With this light-emitting device, the electric charges accumulated in the insulating layer can be reduced.

The light-emitting device according to one aspect may further include:
a substrate,
a first electrode that is provided at the substrate and electrically coupled to the first semiconductor layer,
a second electrode that is provided on a side of the light-emitting unit opposite to the substrate, and electrically coupled to the second semiconductor layer, and
a wiring that is provided at the insulating layer and electrically coupled to the second electrode, wherein
the first semiconductor layer may be provided between the substrate and the light-emitting layer,
the conductive layer may be provided between the substrate and the wiring, and
the predetermined potential may be
a potential between a potential applied to the first electrode and a potential applied to the wiring,
same as the potential applied to the first electrode, or
same as the potential applied to the wiring.

With this light-emitting device, the parasitic capacitance due to the substrate, the wiring, and the insulating layer can be reduced.

In the light-emitting device according to one aspect,
the light-emitting unit may include a plurality of columnar portions, and
each of the plurality of columnar portions may include the first semiconductor layer, the second semiconductor layer, and the light-emitting layer.

With this light-emitting device, dislocations generated in the light-emitting layer can be reduced.

In the light-emitting device according to one aspect, a distance between the conductive layer and the wiring may be shorter than a distance between the conductive layer and the substrate.

With this light-emitting device, noise entering from the wiring can be blocked by the conductive layer before the noise reaches a deep portion of the insulating layer.

In the light-emitting device according to one aspect, the conductive layer may be provided on an opposite side of the light-emitting layer from the substrate, when viewed in a stacking direction of the first semiconductor layer and the light-emitting layer.

With this light-emitting device, noise entering from the wiring can be blocked by the conductive layer before the noise reaches a deep portion of the light-emitting layer.

In the light-emitting device according to one aspect, the conductive layer may surround the light-emitting unit when viewed in a stacking direction of the first semiconductor layer and the light-emitting layer.

With this light-emitting device, the electric charges accumulated around the light-emitting unit can be reduced by the conductive layer.

In the light-emitting device according to one aspect,
the insulating layer may include
a first layer provided between the substrate and the conductive layer, and
a second layer provided between the conductive layer and the wiring, and
a dielectric constant of the second layer may be smaller than a dielectric constant of the first layer.

With this light-emitting device, it is possible to reduce the parasitic capacitance on the wiring side where noise is likely to enter.

A projector according to one aspect includes one aspect of the light-emitting device.

One aspect of a display includes one aspect of the light-emitting device.

One aspect of a head-mounted display includes one aspect of the light-emitting device.

What is claimed is:

1. A light-emitting device, comprising:
a light-emitting unit including a first semiconductor layer, a second semiconductor layer having a conductivity type different from a conductivity type of the first semiconductor layer, and a light-emitting layer provided between the first semiconductor layer and the second semiconductor layer;
an insulating layer that covers the light-emitting unit; and
a conductive layer to which a predetermined potential is applied, the conductive layer being provided in the insulating layer and electrically separated from the light-emitting unit.

2. The light-emitting device according to claim 1, further comprising:
a substrate;
a first electrode that is provided at the substrate and electrically coupled to the first semiconductor layer;
a second electrode that is provided on a side of the light-emitting unit opposite to the substrate, and electrically coupled to the second semiconductor layer; and
a wiring that is provided at the insulating layer and electrically coupled to the second electrode, wherein
the first semiconductor layer is provided between the substrate and the light-emitting layer,
the conductive layer is provided between the substrate and the wiring, and
the predetermined potential is
a potential between a potential applied to the first electrode and a potential applied to the wiring,
same as the potential applied to the first electrode, or
same as the potential applied to the wiring.

3. The light-emitting device according to claim 2, wherein
the light-emitting unit includes a plurality of columnar portions, and
each of the plurality of columnar portions includes the first semiconductor layer, the second semiconductor layer, and the light-emitting layer.

4. The light-emitting device according to claim 2, wherein a distance between the conductive layer and the wiring is shorter than a distance between the conductive layer and the substrate.

5. The light-emitting device according to claim 2, wherein the conductive layer is provided on an opposite side of the light-emitting layer from the substrate, when viewed in a stacking direction of the first semiconductor layer and the light-emitting layer.

6. The light-emitting device according to claim 2, wherein the conductive layer surrounds the light-emitting unit when viewed in a stacking direction of the first semiconductor layer and the light-emitting layer.

7. The light-emitting device according to claim 2, wherein
the insulating layer includes
a first layer provided between the substrate and the conductive layer, and
a second layer provided between the conductive layer and the wiring, and
a dielectric constant of the second layer is smaller than a dielectric constant of the first layer.

8. A projector comprising the light-emitting device according to claim 1.

9. A display comprising the light-emitting device according to claim 1.

10. A head-mounted display comprising the light-emitting device according to claim 1.
